(19) United States
(12) Patent Application Publication
(10) Pub. No.: US 2024/0087971 A1
(43) Pub. Date: Mar. 14, 2024

(54) COPPER CLAD LAMINATE (CCL) FOR PLATING PADS WITHIN A GLASS CAVITY FOR GLASS CORE APPLICATIONS

(71) Applicant: Intel Corporation, Santa Clara, CA (US)

(72) Inventors: Brandon C. MARIN, Gilbert, AZ (US); Gang DUAN, Chandler, AZ (US); Srinivas V. PIETAMBARAM, Chandler, AZ (US); Kristof DARMAWIKARTA, Chandler, AZ (US); Jeremy D. ECTON, Gilbert, AZ (US); Suddhasattwa NAD, Chandler, AZ (US); Hiroki TANAKA, Gilbert, AZ (US); Pooya TADAYON, Portland, OR (US)

(21) Appl. No.: 17/943,915

(22) Filed: Sep. 13, 2022

(51) Int. Cl. H01L 23/15; H01L 23/00; H01L 23/538

(52) U.S. Cl. CPC H01L 23/15; H01L 23/5381; H01L 23/5384; H01L 24/16; H01L 2224/16225

(57) ABSTRACT

Embodiments disclosed herein include interposers and methods of forming interposers. In an embodiment, an interposer comprises a substrate with a first surface and a second surface opposite from the first surface, where the substrate comprises glass. In an embodiment, the interposer further comprises a cavity into the first surface of the substrate, a via through the substrate below the cavity, a first pad in the cavity over the via, and a second pad on the second surface of the substrate under the via.

### TECHNICAL FIELD

Embodiments of the present disclosure relate to electronic packages, and more particularly to package substrates with glass cores that include cavities with vias below the cavities.

### BACKGROUND

Typically, for optical co-packaging of ASIC modules, a printed circuit board (PCB) is used to interface the ASIC with optical transceivers. The optical transceivers are often 1 cm or further away from the ASIC. This causes significant power and signal integrity losses. Glass, especially glass with a cavity, can be used to make the integration simpler and provide more efficient signaling. Furthermore, ultra-flat glass substrates enable improved pick-and-place assembly of prefabricated photonic devices, which has the potential to lower overall cost.

### BRIEF DESCRIPTION OF THE DRAWINGS

FIG. 1 is a cross-sectional illustration of a glass interposer with a cavity that enables coupling of dies together by a bridge in the cavity, in accordance with an embodiment.

FIGS. 2A-2P are cross-sectional illustrations depicting a process for forming a glass interposer similar to the interposer shown in FIG. 1, in accordance with an embodiment.

FIG. 3A is a cross-sectional illustration of a glass interposer with a cavity that includes vias with protrusions above a bottom surface of the cavity, in accordance with an embodiment.

FIG. 3B is a cross-sectional illustration of the via with curved surfaces adjacent to the protrusion above the bottom surface of the cavity, in accordance with an embodiment.

FIGS. 4A-4P are cross-sectional illustrations depicting a process for forming a glass interposer similar to the interposer shown in FIG. 3A, in accordance with an embodiment.

FIG. 5 is a cross-sectional illustration of a glass interposer with a cavity and vias below the cavity that are lined with an adhesion promoting layer, in accordance with an embodiment.

FIGS. 6A-6L are cross-sectional illustrations depicting a process for forming a glass interposer similar to the interposer shown in FIG. 5, in accordance with an embodiment.

FIG. 7 is a cross-sectional illustration of an electronic system with a glass interposer with a cavity, in accordance with an embodiment.

FIG. 8 is a schematic of a computing device built in accordance with an embodiment.

### EMBODIMENTS OF THE PRESENT DISCLOSURE

Described herein are package substrates with glass cores that include cavities with vias below the cavities, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, glass interposers are particularly beneficial for optoelectric systems. However, assembling the glass interposer is not without issue. Particularly, plating vias below the cavity can be a challenging process. Accordingly, embodiments disclosed herein include forming the via openings, and providing a copper clad laminate (CCL) below the via openings. The copper foil of the CCL provides a continuous seed layer that can then be used in order to electrolytically plate up the vias in the via openings. The use of vias below the cavity enables true three dimensional (3D) interconnect architectures in the optoelectronic system.

In some embodiments, the vias include pads at the bottom of the cavity. The bridge die can then be coupled to the pads on the bottom of the cavity. In other embodiments, the bottom of the cavity is recessed after forming the vias. This results in protrusions that extend up into the cavity. The bridge can then be coupled to the protrusions. In yet another embodiment, sidewalls of the via opening may be lined with an adhesion promoting material, such as a material including silicon and nitrogen. This improves the mechanical reliability of the system.

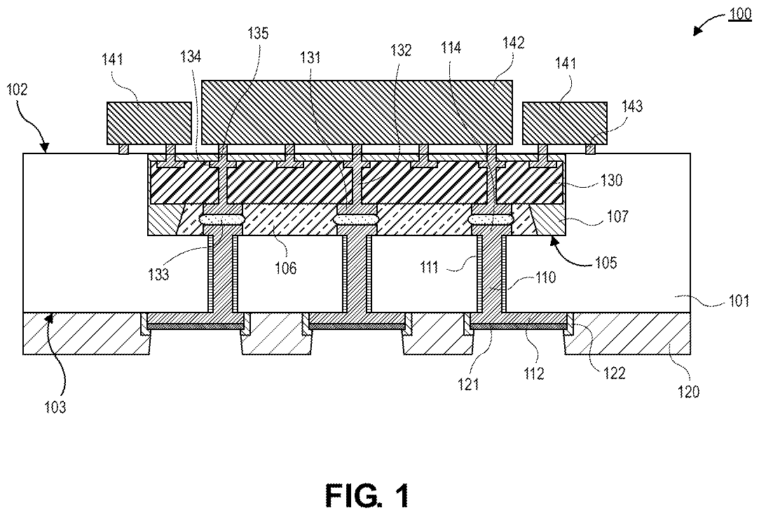

Referring now to FIG. 1, a cross-sectional illustration of an interposer 100 is shown, in accordance with an embodiment. In an embodiment, the interposer 100 comprises a substrate 101. The substrate 101 may comprise glass. Particularly, the substrate 101 may comprise substantially all glass. That is, the substrate 101 may be different than an organic substrate that includes glass fiber reinforcements. In an embodiment, the substrate 101 may be a glass formulation that is compatible with laser assisted patterning operations. For example, the substrate 101 may comprise borosilicate glass or fused silica glass. In a laser assisted patterning operation, a laser is used to expose regions of the substrate 101. The exposed regions undergo a microstructure and/or phase change. The modified regions of the substrate 101 can then be selectively etched with respect to the unexposed regions of the substrate 101 (e.g., with a wet etching process). In the embodiments shown herein, the patterning of the substrate 101 results in substantially vertical sidewalls. However, it is to be appreciated that the patterned sidewalls of the substrate 101 may be tapered.

In an embodiment, the substrate 101 may comprise a cavity 105 into a first surface 102 of the substrate 101. The cavity 105 may be formed to a depth in order to accommodate a bridge 130. The bridge 130 may include conductive routing (e.g., pads 131 and 134, and vias 132. Bumps 135 may be provided over the pads 134. In an embodiment, high density routing (e.g., traces, etc.) may be provided on the bridge 130. The high density routing may be used to electrically couple first dies 141 to a second die 142. The first dies 141 may be photonic integrated circuits (PICs), and the second die 142 may be a compute die, such as a processor, an ASIC, or the like. The first dies 141 may be optically coupled to a waveguide (not shown) integrated into the substrate 101 or on the substrate 101. In an embodiment, the bridge 130 may be surrounded by a fill layer 107 that fills a remaining volume of the cavity 105.

In an embodiment, through glass vias (TGVs) 110 may be provided through the substrate 101 below the cavity 105. The TGVs 110 may have vertical sidewalls. In other embodiments, the TGVs 110 may have tapered sidewalls. The TGVs 110 may be over a seed layer 111 that lines the via openings. In an embodiment, first pads 114 are provided over the TGVs 110 at the bottom of the cavity 105. The first pads 114 may be electrically coupled to pads 131 of the bridge 130 by solder 133 or any other suitable interconnect architecture. The solder 133 may be surrounded by an underfill 106.

In an embodiment, second pads 112 may be provided on a second surface 103 of the substrate 101 below the TGVs 110. The second pads 112 may have a surface finish 121. Additionally, an adhesion promoting layer 122 may be provided over portions of the second pads 112 and the surface finish 121. In an embodiment, a solder resist layer 120 is provided over the second surface 103 of the substrate 101. Openings through the solder resist layer 120 may be used to expose the second pads 112.

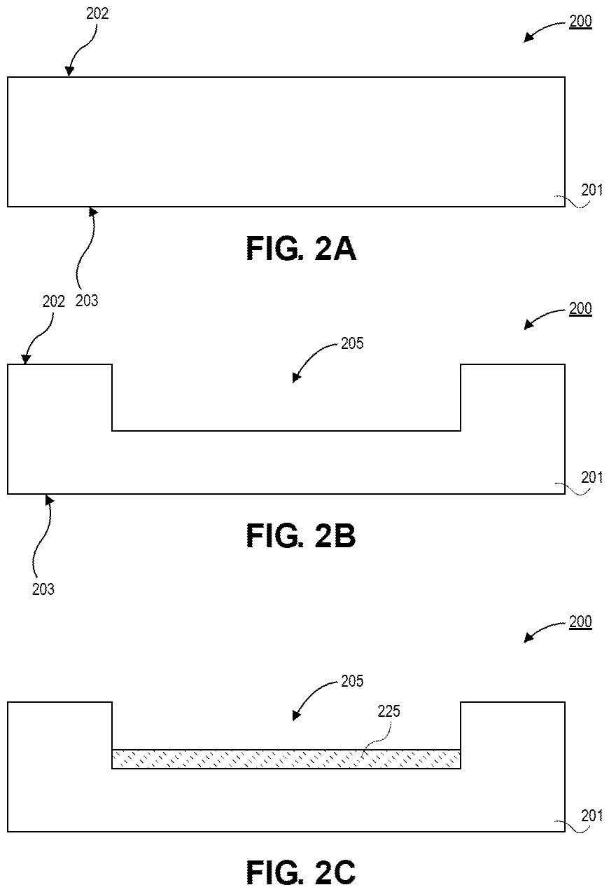

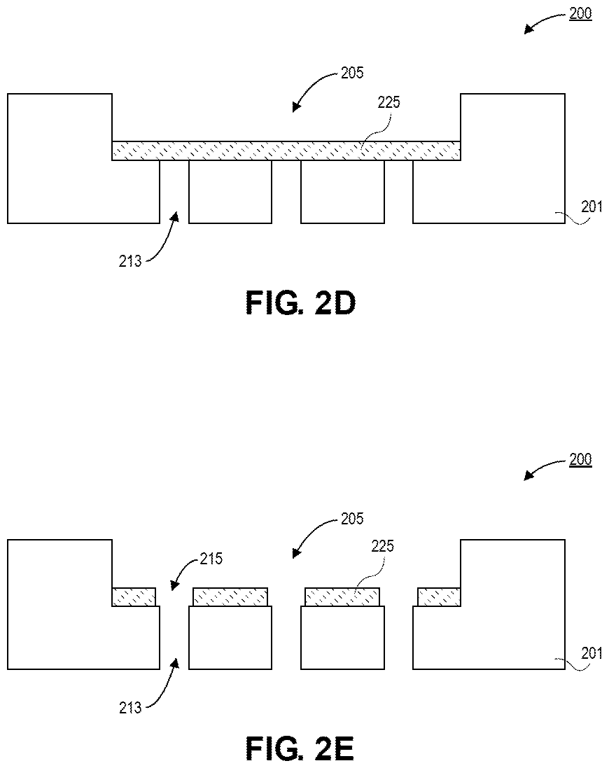

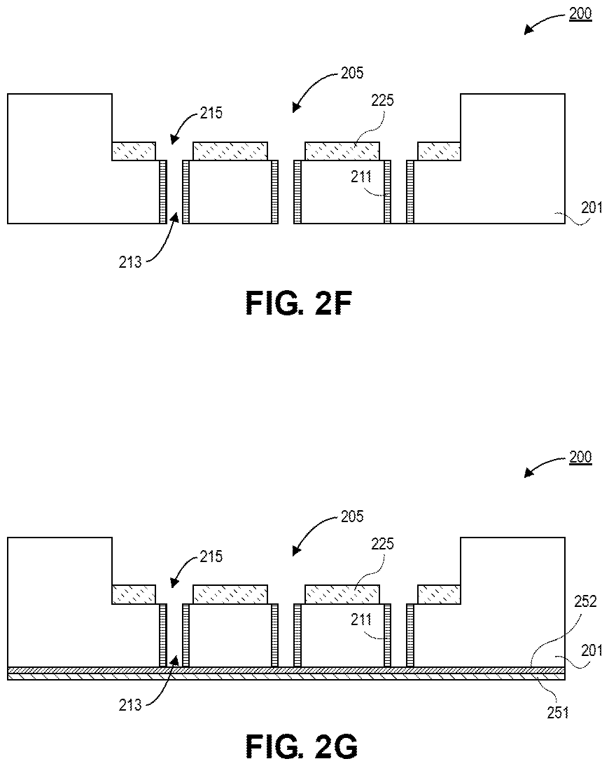

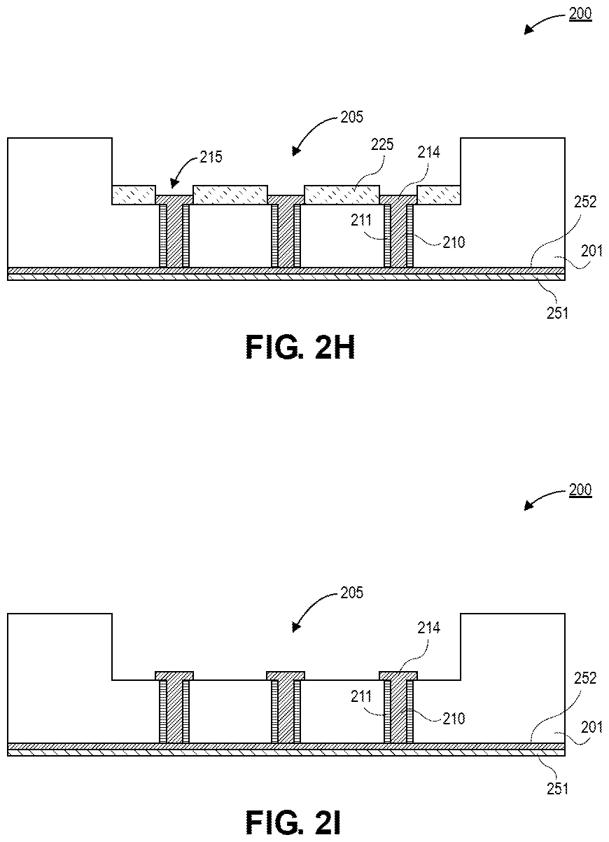

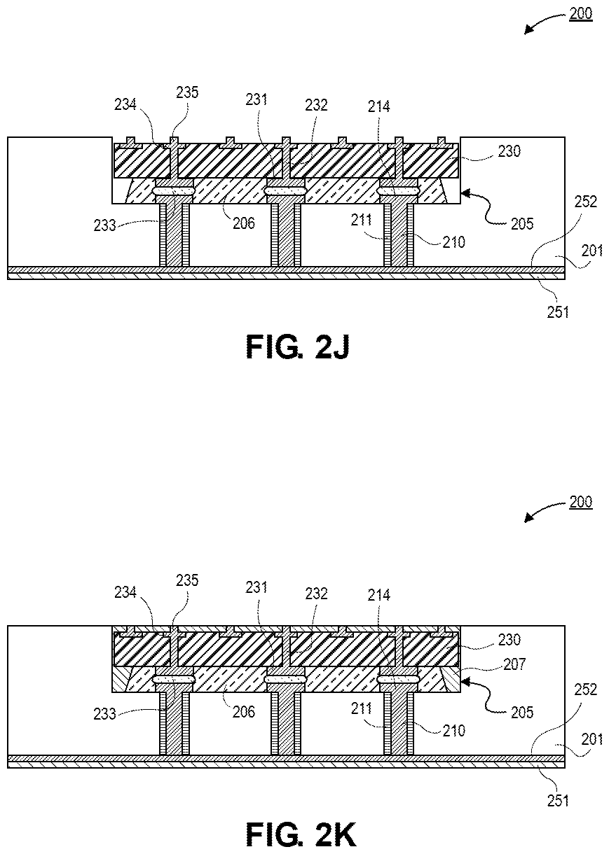

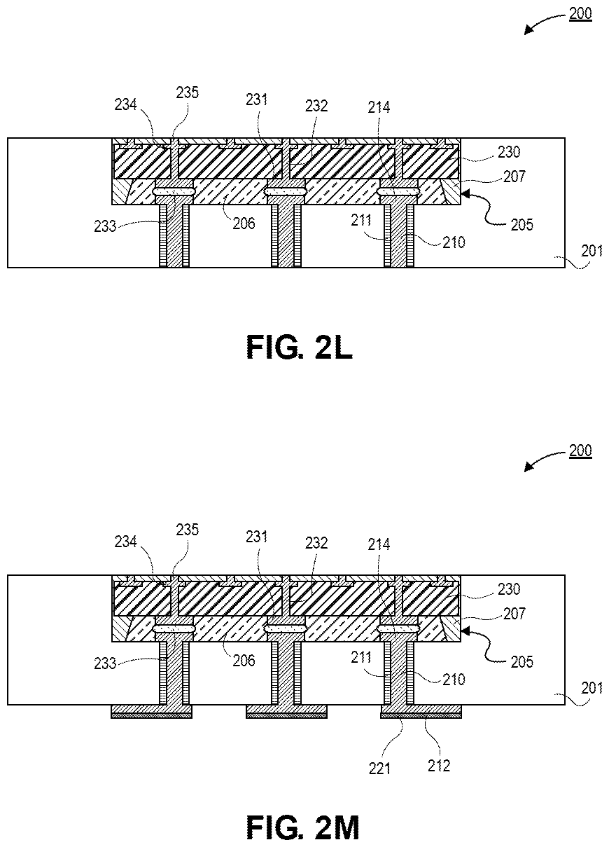

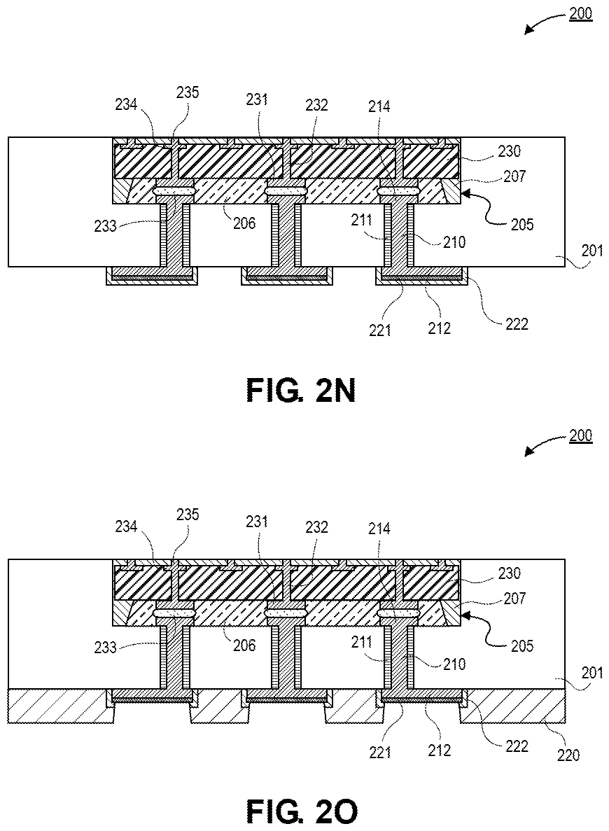

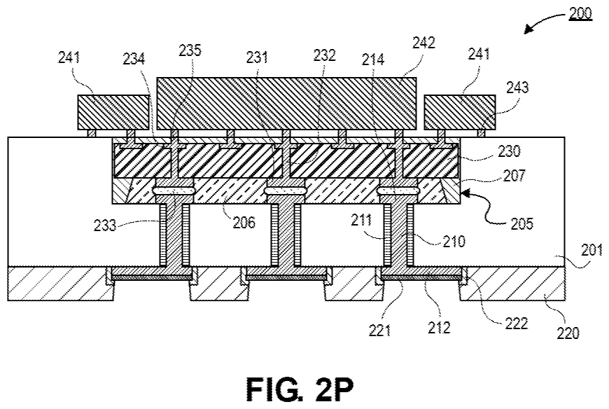

Referring now to FIGS. 2A-2P, a series of cross-sectional illustrations depicting a process for forming an interposer 200 is shown, in accordance with an embodiment. In an embodiment, the interposer 200 may be similar to the interposer 100 described above with respect to FIG. 1.

Referring now to FIG. 2A, a cross-sectional illustration of an interposer 200 at a stage of manufacture is shown, in accordance with an embodiment. In an embodiment, the interposer 200 comprises a substrate 201. The substrate 201 may be a glass substrate 201. The substrate 201 may have any suitable thickness. In a particular embodiment, the substrate 201 may have a thickness between approximately 100 μm and approximately 5,000 μm. As used herein, “approximately” may refer to a range of values within ten percent of the stated value. For example approximately 100 μm refers to a range of values between 90 μm and 110 μm. In an embodiment, the substrate 201 may have a formulation suitable for laser assisted patterning operations. The substrate 201 may have a first surface 202 and a second surface 203 opposite from the first surface.

Referring now to FIG. 2B, a cross-sectional illustration of the interposer 200 after a cavity 205 is formed in the substrate 201 is shown, in accordance with an embodiment. In an embodiment, the cavity 205 is formed with a laser assisted etching process. While shown as having substantially vertical sidewalls, it is to be appreciated that the cavity 205 may have tapered sidewalls in some embodiments. In an embodiment, the depth of the cavity 205 may be approximately half the thickness of the substrate 201 or less. Though, it is to be appreciated that deeper cavities 205 may also be used in some embodiments. The cavity 205 may be formed into the first surface 202 of the substrate 201.

Referring now to FIG. 2C, a cross-sectional illustration of the interposer 200 after a resist layer 225 is provided in the cavity 205 is shown, in accordance with an embodiment. In an embodiment, the resist layer 225 may be deposited with any suitable deposition process. The resist layer 225 may be a dry film resist (DFR) or a photoimageable dielectric (PID). The resist layer 225 is shown as partially filling the cavity 205. However, in other embodiments, the resist layer 225 may fully fill the cavity 205.

Referring now to FIG. 2D, a cross-sectional illustration of the interposer 200 after via openings 213 are formed is shown, in accordance with an embodiment. In an embodiment, the via openings 213 may be formed below the cavity 205. The via openings 213 may pass from the bottom of the cavity 205 to the bottom of the substrate 201. In the illustrated embodiment, the via openings 213 have substantially vertical sidewalls. However, in other embodiments, the via openings 213 may have tapered sidewalls. For example a diameter of the opening at the bottom of the cavity 205 may be narrower than a diameter of the opening at a bottom of the substrate 201. The via openings 213 may be formed with a laser assisted patterning process.

Referring now to FIG. 2E, a cross-sectional illustration of the interposer 200 after pad openings 215 are formed into the resist layer 225 is shown, in accordance with an embodiment. The pad openings 215 may be formed with any suitable patterning process. In the case of a PID resist layer 225, the resist layer 225 may be directly exposed and patterned. In an embodiment, the pad openings 215 may be provided over the via openings 213. The pad openings 215 may have a width that is greater than a width of the via openings 213.

Referring now to FIG. 2F, a cross-sectional illustration of the interposer 200 after a seed layer 213 is deposited is shown, in accordance with an embodiment. In an embodiment, the seed layer 213 may be formed along sidewalls of the via openings 213. While not shown anywhere else, it is to be appreciated that the seed layer 213 may also be provided along other surfaces of the interposer 201.

Referring now to FIG. 2G, a cross-sectional illustration of the interposer 200 after a CCL 251/252 is applied over a bottom surface of the substrate 201. The CCL may include a dielectric layer 251 and a copper foil 252 or other conductive material. The CCL 251/252 may cover the bottom of the via openings 213. As such, the plating of the via openings 213 may occur from the bottom up in some embodiments.

Referring now to FIG. 2H, a cross-sectional illustration of the interposer 200 after TGVs 210 and first pads 214 are formed is shown, in accordance with an embodiment. In an embodiment, the TGVs 210 and the first pads 214 may be formed with any suitable plating process. For example, an electrolytic plating process may be used in order to form the TGVs 210 and the pads 214. In an embodiment, a thickness of the pads 214 may be smaller than a thickness of the resist layer 225. That is, the pad openings 215 may not be fully filled with the conductive material. The TGVs 210 and the first pads 214 may comprise copper or any other suitable conductive material (or materials).

Referring now to FIG. 2I, a cross-sectional illustration of the interposer 200 after the resist layer 225 is removed is shown, in accordance with an embodiment. In an embodiment, the resist layer 225 may be removed with a resist stripping process, an etching process, or the like. Removal of the resist layer 225 fully exposes the first pads 214.

Referring now to FIG. 2J, a cross-sectional illustration of the interposer 200 after a bridge 230 is inserted into the cavity 205 is shown, in accordance with an embodiment. The bridge 230 may be electrically coupled to the first pads 214. For example, pads 231 of the bridge 230 may be coupled to first pads 214 by an interconnect 233, such as solder or the like. In an embodiment, the bridge 230 may further comprise vias 232 that connect pads 231 to pads 234. Bumps 235, such as copper bumps 235, may be provided over the pads 234. The tops of the bumps 235 may be above a top surface of the substrate 201. In an embodiment, an underfill layer 206 may be provided between the bridge 230 and the bottom of the cavity 205. The underfill layer 206 may surround the interconnects 233.

Referring now to FIG. 2K, a cross-sectional illustration of the interposer 200 after a cavity fill layer 207 is dispensed into the cavity 205 is shown, in accordance with an embodiment. The cavity fill layer 207 may substantially fill the remaining volume of the cavity 205. The cavity fill layer 207 may be dispensed with any suitable process. In an embodiment, excess cavity fill layer 207 that is outside of the cavity may be removed with a polishing or grinding process (e.g., chemical mechanical planarization (CMP)). The polishing process may also recess the top surfaces of the bumps 235 so that the top surfaces of the bumps 235 are substantially coplanar with the top surface of the substrate 201.

Referring now to FIG. 2L, a cross-sectional illustration of the interposer 200 after the CCL layer is removed is shown, in accordance with an embodiment. In some instances, both the dielectric layer 251 and the copper foil 252 are removed in order to fully expose the backside surface of the substrate 201. In other embodiments, the copper foil 252 may remain on the backside surface of the substrate 201 in order to allow for plating of second pads without the need of forming a seed layer. The CCL layer 251/252 may be removed with a stripping process, a delamination process, and/or an etching process.

Referring now to FIG. 2M, a cross-sectional illustration of the interposer 200 after second pads 212 are formed over a bottom surface of the substrate 201 is shown, in accordance with an embodiment. In an embodiment, the second pads 212 may be provided below the TGVs 210. That is, the TGVs 210 may provide an electrical connection between first pads 214 and the second pads 212. In an embodiment, a surface finish 221 may be provided over surfaces of the second pads 212. The surface finish 221 may include one or more layers of conductive material. For example, the surface finish 221 may include nickel, palladium, and gold. Though, other surface finish architectures may also be used.

Referring now to FIG. 2N, a cross-sectional illustration of the interposer 200 after an adhesion promoting layer 222 is provided over a backside of the substrate 201 is shown, in accordance with an embodiment. The adhesion promoting layer 222 is shown as being only over the second pads 212 and the surface finish 221. However, it is to be appreciated that the adhesion promoting layer 222 may also be provided over a backside surface of the substrate 201. In an embodiment, the adhesion promoting layer 222 may comprise silicon and nitrogen (e.g., silicon nitride) or any other material system that improves adhesion between a solder resist and the substrate 201.

Referring now to FIG. 2O, a cross-sectional illustration of the interposer 200 after a solder resist layer 220 is applied over the backside of the substrate 201 is shown, in accordance with an embodiment. In an embodiment, the solder resist layer 220 may be applied with a lamination process or any other suitable process. Solder resist openings may be formed through the solder resist layer 220 in order to expose the second pads 212. The second pads 212 may maintain the surface finish 221. However, the portion of the adhesion promoting layer 222 within the solder resist openings is removed in order to provide access to the second pads 212.

Referring now to FIG. 2P, a cross-sectional illustration of the interposer 200 after first dies 241 and a second die 242 are attached is shown, in accordance with an embodiment. In an embodiment, the first dies 241 may comprise PICs. The second die 242 may include a compute die, such as a processor, an ASIC, or the like. In an embodiment, high density routing on the bridge 230 may provide electrical coupling between the first dies 241 and the second die 242. For example, bumps 243 on the dies 241/242 may be coupled to bumps 235 of the bridge 230. For example, a hybrid bonding process may be used in some embodiments. However, it is to be appreciated that any first level interconnect (FLI) architecture may be used to couple the dies 241/242 to the bridge 230.

Though not shown, it is to be appreciated that the first dies 241 may be optically coupled to an optical interconnect. For example, an optical waveguide (not shown) may be integrated into the substrate 201. Other optical waveguide architectures may also be used to provide an optical interconnect to the first dies 241. As such, the interposer 200 may be considered an optoelectronic device since the interposer sends/receives optical signals while the second die 242 operates in the electrical regime.

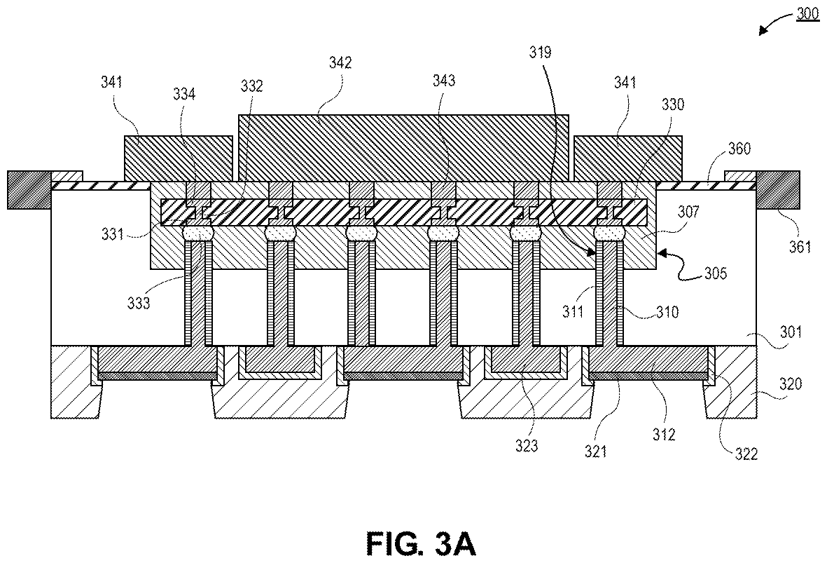

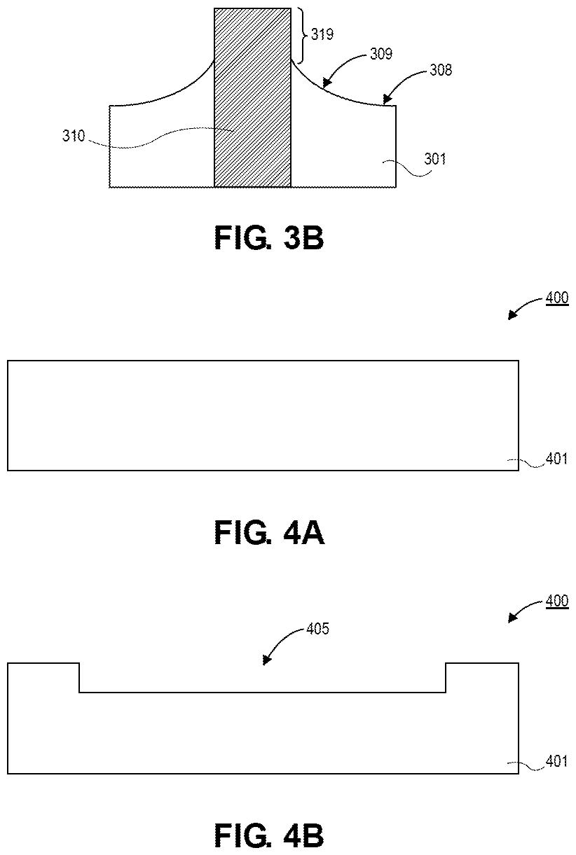

Referring now to FIG. 3A, a cross-sectional illustration of an interposer 300 is shown, in accordance with an additional embodiment. In an embodiment, the interposer 300 comprises a substrate 301, such as a glass substrate 301. The substrate 301 may include a cavity 305 formed into a top surface of the substrate 301. In an embodiment, TGVs 310 may pass through the substrate 301 below the cavity 305. The TGVs 310 may be lined with a seed layer 311. Additionally, the bottom of the cavity 305 may be recessed in order to form via protrusions 319 that extend up from the bottom of the cavity 305.

The via protrusions 319 may be coupled to pads 331 of a bridge 330 by interconnects 333. The bridge 330 may also include vias 332 and top pads 334. The bridge 330 may include high density routing in order to electrically couple first dies 341 to a second die 342. In an embodiment, the first dies 341 may be PICs and the second die 342 may be a compute die, such as a processor, an ASIC, or the like. The first dies 341 may be optically coupled to a fiber connector 361 by waveguides 360. The waveguides 360 may be fabricated into the surface of the substrate 360. In an embodiment, the first dies 341 and the second die 342 may be coupled to the bridge 330 by bumps 343 or any other suitable FLI architecture. In an embodiment, the bridge 330 may be surrounded by a cavity fill layer 307.

In an embodiment pads 312 may be provided below the TGVs 310 on a backside surface of the substrate 301. Traces 323 may also be provided adjacent to the pads 312. In an embodiment, the pads 312 may be covered by a surface finish 321 (e.g., nickel, palladium, gold). An adhesion promoting layer 322 (e.g., silicon nitride) may be provided over the pads 312, traces 323, and the backside of the substrate 301. A solder resist layer 320 may be applied over the pads 312. Solder resist openings may expose the pads 312.

Referring now to FIG. 3B, a zoomed in cross-sectional illustration depicting one of the protrusions 319 is shown, in accordance with an embodiment. In an embodiment, the protrusion 319 extends up past a bottom surface 308 of the cavity 305 in the substrate 301. The surface 309 of the substrate 301 adjacent to the protrusion 319 may be curved. That is, an etching process used to etch the substrate 301 and provide the protrusion 319 from the TGV 310 may not uniformly etch the substrate 301. This results in the surface 309 interfacing with the protrusion 319 not being orthogonal to the protrusion 319.

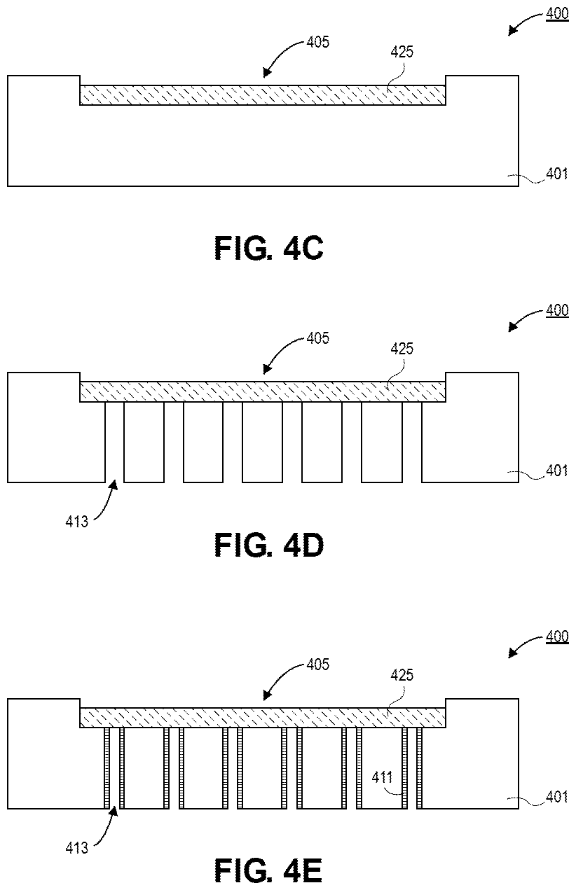

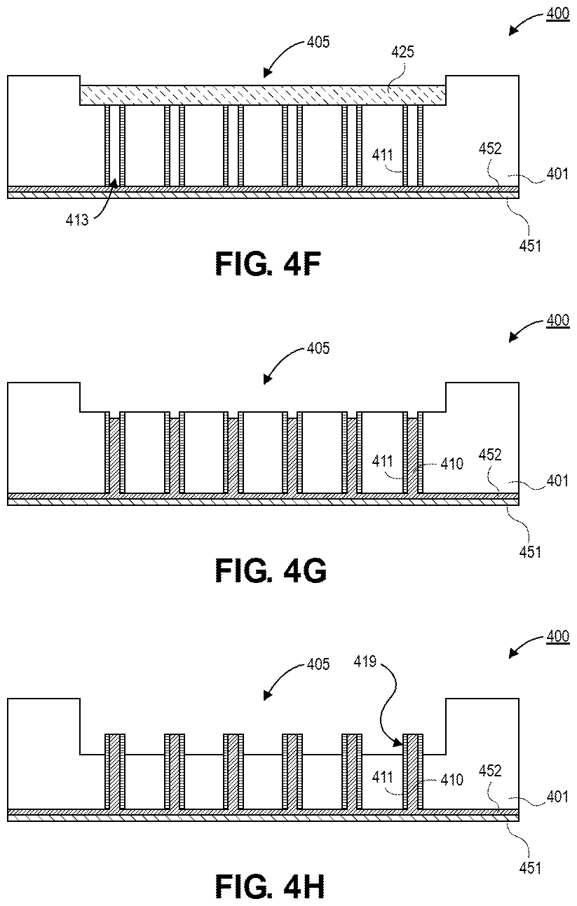

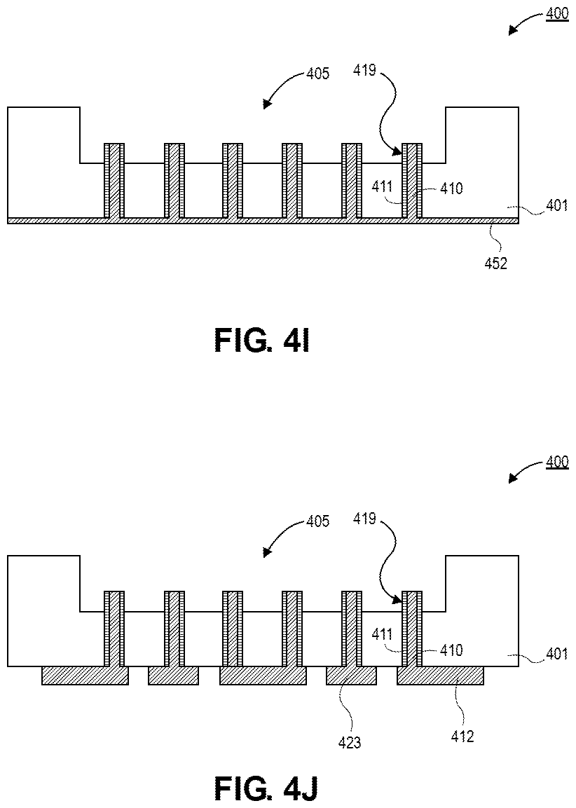

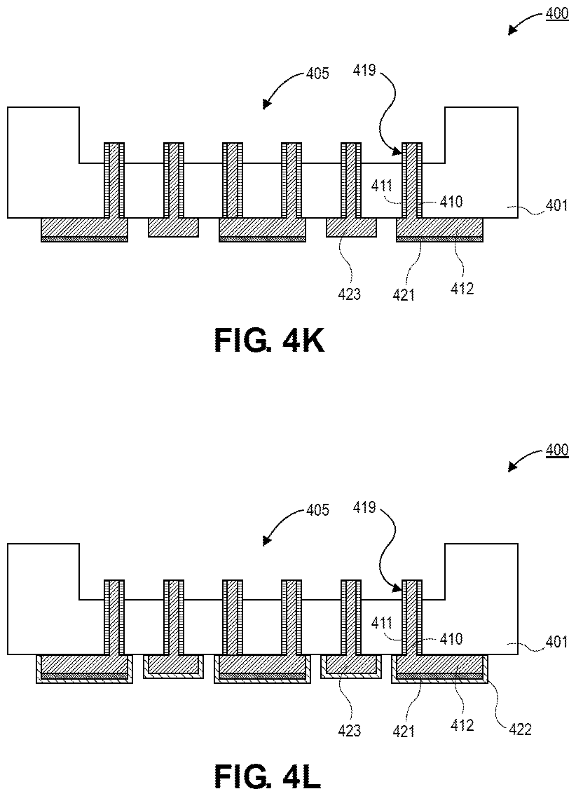

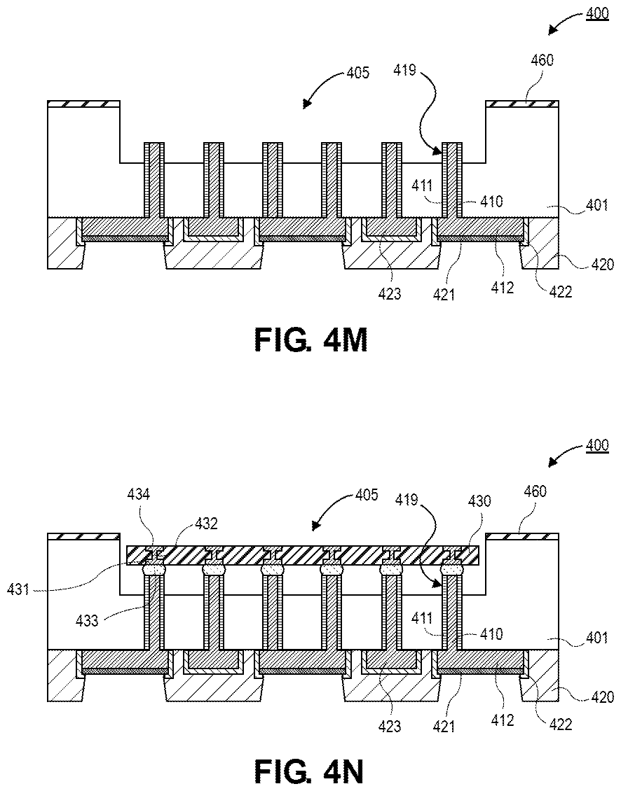

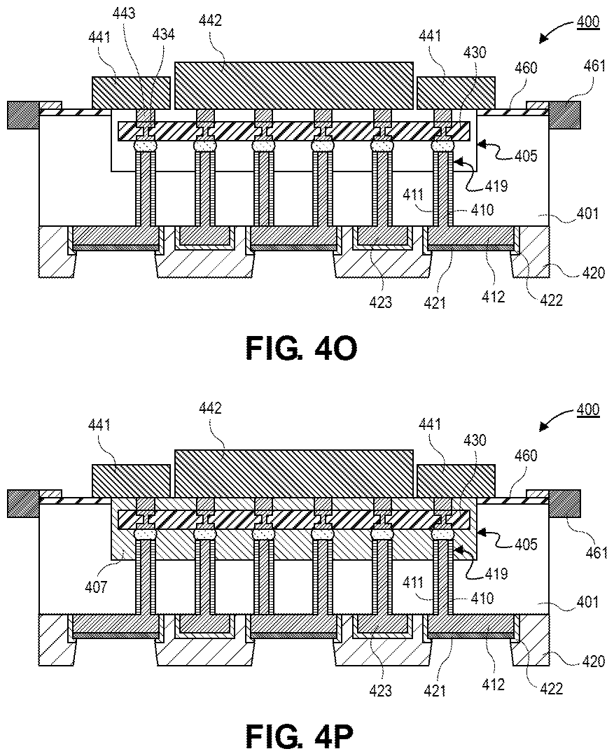

Referring now to FIGS. 4A-4P, a series of cross-sectional illustrations depicting a process for forming an interposer 400 is shown, in accordance with an embodiment. The interposer 400 may be substantially similar to the interposer 300 shown in FIG. 3A.

Referring now to FIG. 4A, a cross-sectional illustration of an interposer 400 at a stage of manufacture is shown, in accordance with an embodiment. In an embodiment, the interposer 400 comprises a substrate 401. The substrate 401 may be a glass substrate 401. The substrate 401 may have any suitable thickness. In a particular embodiment, the substrate 401 may have a thickness between approximately 100 μm and approximately 5,000 μm. In an embodiment, the substrate 401 may have a formulation suitable for laser assisted patterning operations.

Referring now to FIG. 4B, a cross-sectional illustration of the interposer 400 after a cavity 405 is formed in the substrate 401 is shown, in accordance with an embodiment. In an embodiment, the cavity 405 is formed with a laser assisted etching process. While shown as having substantially vertical sidewalls, it is to be appreciated that the cavity 405 may have tapered sidewalls in some embodiments. In an embodiment, the depth of the cavity 405 may be approximately half the thickness of the substrate 401 or less. Though, it is to be appreciated that deeper cavities 405 may also be used in some embodiments.

Referring now to FIG. 4C, a cross-sectional illustration of the interposer 400 after a resist layer 425 is provided in the cavity 405 is shown, in accordance with an embodiment. In an embodiment, the resist layer 425 may be deposited with any suitable deposition process. The resist layer 425 may be a DFR or a PID. The resist layer 425 is shown as partially filling the cavity 405. However, in other embodiments, the resist layer 425 may fully fill the cavity 405.

Referring now to FIG. 4D, a cross-sectional illustration of the interposer 400 after via openings 413 are formed is shown, in accordance with an embodiment. In an embodiment, the via openings 413 may be formed below the cavity 405. The via openings 413 may pass from the bottom of the cavity 405 to the bottom of the substrate 401. In the illustrated embodiment, the via openings 413 have substantially vertical sidewalls. However, in other embodiments, the via openings 413 may have tapered sidewalls. For example a diameter of the opening at the bottom of the cavity 405 may be narrower than a diameter of the opening at a bottom of the substrate 401. The via openings 413 may be formed with a laser assisted patterning process.

Referring now to FIG. 4E, a cross-sectional illustration of the interposer 400 after a seed layer 411 is applied is shown, in accordance with an embodiment. In an embodiment, the seed layer 411 may be provided along sidewalls of the via openings 413. While not shown, it is to be appreciated that the seed layer 411 may also be applied along other surfaces of the interposer 400.

Referring now to FIG. 4F, a cross-sectional illustration of the interposer 400 after a CCL 451/452 is applied over the bottom surface of the substrate 401 is shown, in accordance with an embodiment. The CCL may include a dielectric layer 451 and a copper foil 452 or other conductive layer. The CCL 451/452 may cover the bottom of the via openings 413. As such, the TGVs in the via openings 413 may be plated from the bottom up.

Referring now to FIG. 4G, a cross-sectional illustration of the interposer 400 after the TGVs 410 are formed is shown, in accordance with an embodiment. In an embodiment, the TGVs 410 are formed after the resist layer 425 is removed. The resist layer 425 may be completely removed from the cavity 405, or portions of the resist layer 425 may be removed to expose the via openings 413. In an embodiment, the TGVs 410 may be formed with any suitable plating process, such as an electrolytic plating process. The TGVs 410 may not fully fill the via opening 413 in some embodiments.

Referring now to FIG. 4H, a cross-sectional illustration of the interposer 400 after the bottom of the cavity 405 is recessed is shown, in accordance with an embodiment. In an embodiment, the cavity 405 may be recessed with a wet timed etching process. Recessing the cavity 405 may result in the TGVs 410 extending up past a bottom surface of the cavity 405. The portions of the TGVs 410 above the bottom surface of the cavity 405 may be referred to as protrusions 419.

Referring now to FIG. 4I, a cross-sectional illustration of the interposer 400 after the dielectric layer 451 of the CCL is removed is shown, in accordance with an embodiment. In an embodiment, the dielectric layer 451 may be remove with a stripping, delamination, or etching process. The residual copper foil 452 may allow for subsequent plating on the backside of the substrate 401.

Referring now to FIG. 4J, a cross-sectional illustration of the interposer 400 after pads 412 and traces 423 are formed on the backside of the substrate 401 is shown, in accordance with an embodiment. In an embodiment, the pads 412 and the traces 423 may be provided below the TGVs 410. The pads 412 and traces 423 may be plated with any suitable plating process. After plating, any seed layer 411 or copper foils 452 may be etched away with a flash etching process.

Referring now to FIG. 4K, a cross-sectional illustration of the interposer 400 after a surface finish 421 is applied over the pads 412 is shown, in accordance with an embodiment. The surface finish 421 may comprise any surface finish material system (e.g., nickel, palladium, gold). The surface finish 421 may be selectively applied over the pads 412. That is, the traces 423 may not include the surface finish 421 in some embodiments.

Referring now to FIG. 4L, a cross-sectional illustration of the interposer 400 after an adhesion promoting layer 422 is applied over the pads 412 and traces 423 is shown, in accordance with an embodiment. In an embodiment, the adhesion promoting layer 422 may comprise silicon and nitrogen (e.g., silicon nitride). The adhesion promoting layer 422 may also be provided directly on the backside of the substrate 401.

Referring now to FIG. 4M, a cross-sectional illustration of the interposer 400 after a solder resist layer 420 is applied over the backside of the substrate 401 is shown, in accordance with an embodiment. The solder resist layer 420 may comprise openings in order to expose the pads 412. The portion of the adhesion promoting layer 422 in the solder resist openings may be removed in order to expose the surface finish 421 over the pads 412.

In an embodiment, FIG. 4M also shows the formation of waveguides 460. The waveguides 460 may be formed with a laser exposure process. The laser may alter the morphology of the substrate 401 in order to locally change the refractive index so that the substrate 401 operates as an optical waveguide.

Referring now to FIG. 4N, a cross-sectional illustration of the interposer 400 after a bridge 430 is inserted into the cavity 405 is shown, in accordance with an embodiment. The bridge 430 may comprise first pads 431 and second pads 434. The first pads 431 may be coupled to the second pads 434 by vias 432 through the bridge 430. The first pads 431 may be coupled to protrusions 419 by interconnects 433, such as solder interconnects.

Referring now to FIG. 4O, a cross-sectional illustration of the interposer 400 after first dies 441 and a second die 442 are attached is shown, in accordance with an embodiment. In an embodiment, the first dies 441 may comprise PICs and the second die 442 may be a compute die such as a process, ASIC, or the like. The first dies 441 may be optically coupled to a fiber connector 461 by the waveguides 460. The first dies 441 and the second die 442 may be coupled to the bridge 430 by bumps 443 or any other FLI interconnect architecture.

Referring now to FIG. 4P, a cross-sectional illustration of the interposer 400 after a cavity fill layer 407 is dispensed in the cavity 405 is shown, in accordance with an embodiment. In an embodiment, the cavity fill layer 407 may substantially fill the remainder of the cavity 405 not occupied by the bridge 430, the protrusions 419, the interconnects 422 and the bumps 443.

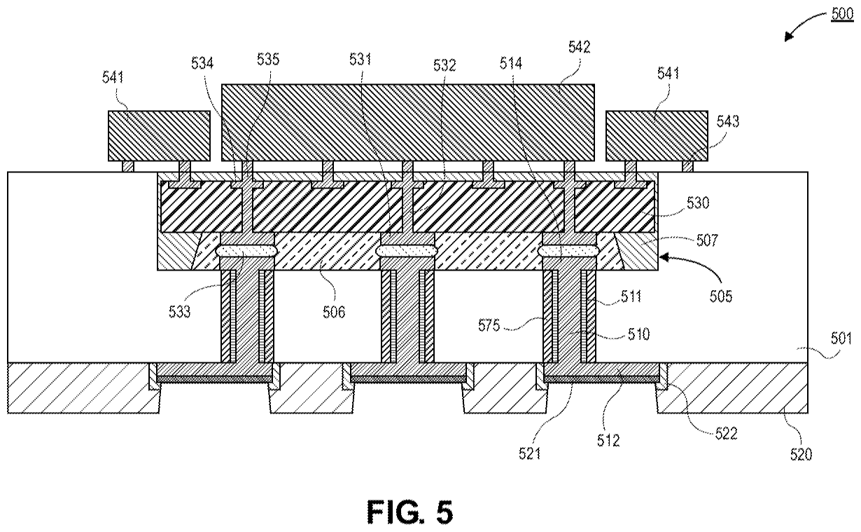

Referring now to FIG. 5, a cross-sectional illustration of an interposer 500 is shown, in accordance with an embodiment. In an embodiment, the interposer 500 comprises a substrate 501, such as a glass substrate 501. The substrate 501 may include a cavity 505. TGVs 510 may be provided through the substrate 501 below the cavity 505. The TGVs 510 may be lined with a seed layer 511 and an adhesion promoting layer 575. The adhesion promoting layer 575 may be in direct contact with the substrate 501. In an embodiment, first pads 514 are provided at a bottom of the cavity 505, and second pads 512 are provided below the substrate 501. The TGVs 510 may electrically couple the first pads 514 to the second pads 512. In an embodiment, the second pads 512 may be covered by a surface finish 521. An adhesion promoting layer 522 may also be provided over the second pads 512. A solder resist layer 520 may have openings to expose the second pads 512.

In an embodiment, a bridge 530 is provided in the cavity 505. The bridge 530 may include pads 531 that are coupled to the first pads 514 by solder 533 or the like. The solder 533 may be surrounded by an underfill 506. The bridge 530 may further comprise vias 532 that couple pads 531 to pads 534. Bumps 535 may be coupled to bumps 543 of the first dies 541 and the second die 542. The first dies 541 may comprise PICs, and the second die 542 may be a compute die, such as a processor, an ASIC, or the like. A cavity fill layer 507 may fill a remainder of the cavity 505.

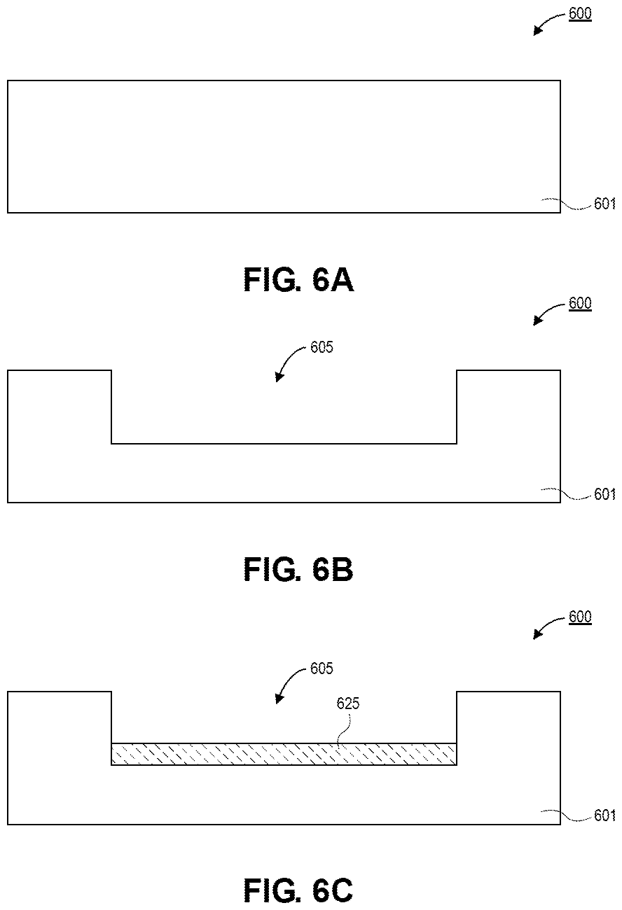

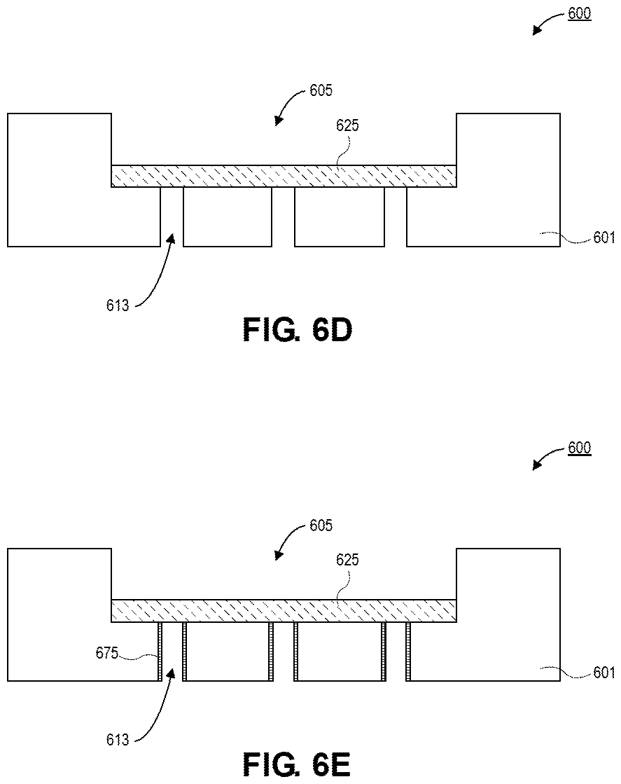

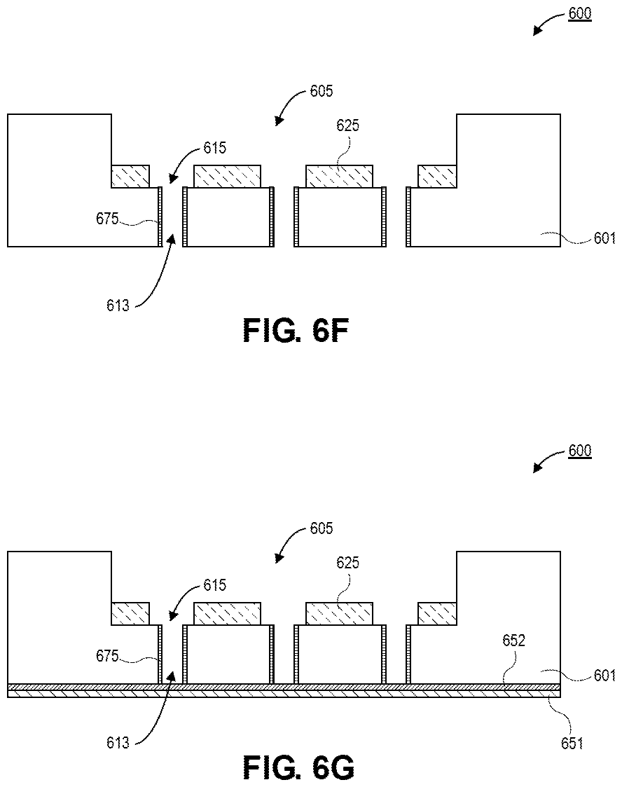

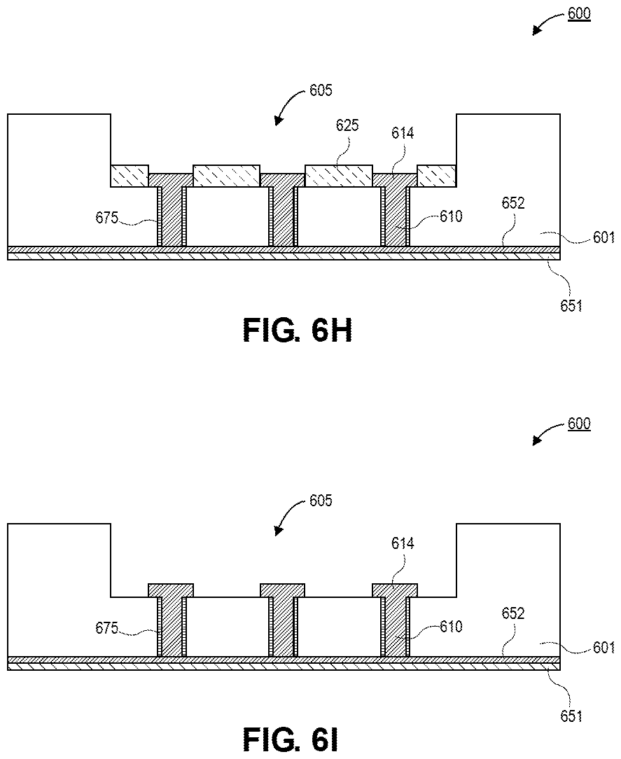

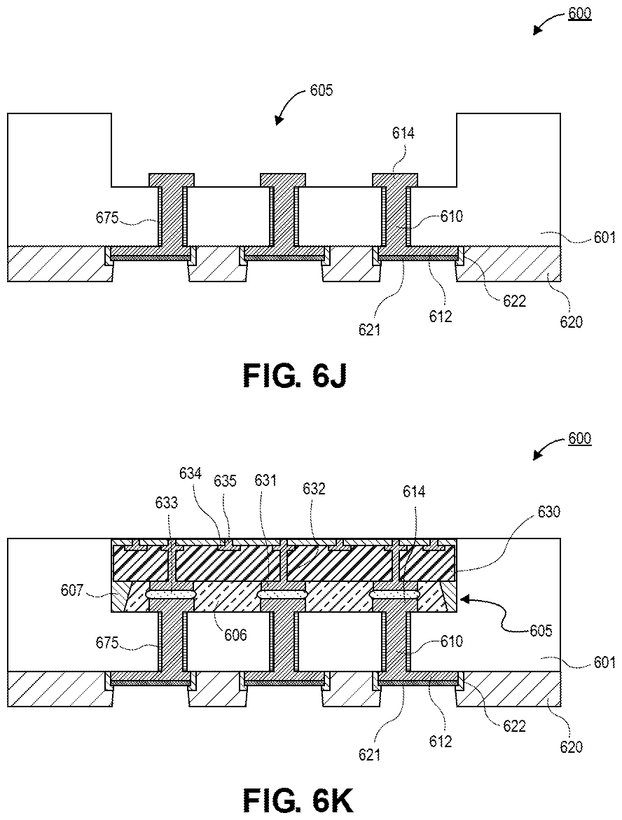

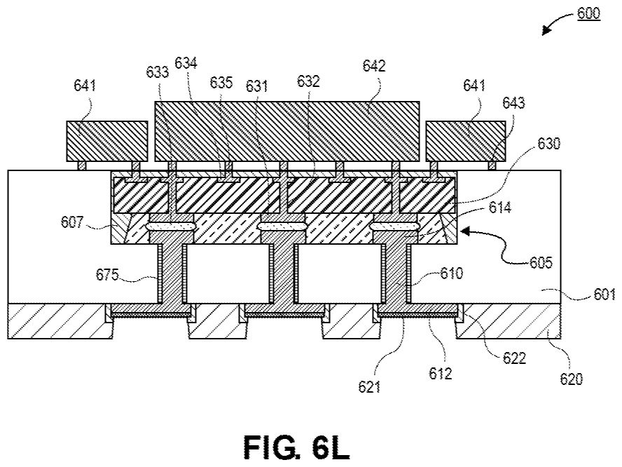

Referring now to FIGS. 6A-6L, a series of cross-sectional illustrations depicting a process for forming an interposer 600 is shown, in accordance with an embodiment. In an embodiment, the interposer 600 may be substantially similar to the interposer 500 in FIG. 5.

Referring now to FIG. 6A, a cross-sectional illustration of an interposer 600 at a stage of manufacture is shown, in accordance with an embodiment. In an embodiment, the interposer 600 comprises a substrate 601. The substrate 601 may be a glass substrate 601. The substrate 601 may have any suitable thickness. In a particular embodiment, the substrate 601 may have a thickness between approximately 100 μm and approximately 5,000 μm. In an embodiment, the substrate 601 may have a formulation suitable for laser assisted patterning operations.

Referring now to FIG. 6B, a cross-sectional illustration of the interposer 600 after a cavity 605 is formed in the substrate 601 is shown, in accordance with an embodiment. In an embodiment, the cavity 605 is formed with a laser assisted etching process. While shown as having substantially vertical sidewalls, it is to be appreciated that the cavity 605 may have tapered sidewalls in some embodiments. In an embodiment, the depth of the cavity 605 may be approximately half the thickness of the substrate 601 or less. Though, it is to be appreciated that deeper cavities 605 may also be used in some embodiments.

Referring now to FIG. 6C, a cross-sectional illustration of the interposer 600 after a resist layer 625 is provided in the cavity 605 is shown, in accordance with an embodiment. In an embodiment, the resist layer 625 may be deposited with any suitable deposition process. The resist layer 625 may be a DFR or a PID. The resist layer 625 is shown as partially filling the cavity 605. However, in other embodiments, the resist layer 625 may fully fill the cavity 605.

Referring now to FIG. 6D, a cross-sectional illustration of the interposer 600 after via openings 613 are formed is shown, in accordance with an embodiment. In an embodiment, the via openings 613 may be formed below the cavity 605. The via openings 613 may pass from the bottom of the cavity 605 to the bottom of the substrate 601. In the illustrated embodiment, the via openings 613 have substantially vertical sidewalls. However, in other embodiments, the via openings 613 may have tapered sidewalls. For example a diameter of the opening at the bottom of the cavity 605 may be narrower than a diameter of the opening at a bottom of the substrate 601. The via openings 613 may be formed with a laser assisted patterning process.

Referring now to FIG. 6E, a cross-sectional illustration of the interposer 600 after an adhesion promoting layer 675 is applied over the sidewalls of the via openings 613 is shown, in accordance with an embodiment. In an embodiment, the adhesion promoting layer 675 may comprise silicon and nitrogen (e.g., silicon nitride). The adhesion promoting layer 675 may also be formed over the bottom surface of the substrate 601 in some embodiments.

Referring now to FIG. 6F, a cross-sectional illustration of the interposer 600 after openings 615 are formed in the resist layer 625 is shown, in accordance with an embodiment. The openings 615 may be wider than the via openings 613.

Referring now to FIG. 6G, a cross-sectional illustration of the interposer 600 after a CCL 651/652 is applied over a bottom surface of the substrate 601 is shown, in accordance with an embodiment. In an embodiment, the CCL may comprise a dielectric layer 651 and a copper foil 652 or other conductive layer. The CCL 651/652 is applied across the bottoms of the via openings 613. As such, the TGVs may be plated up from the CCL 651/652.

Referring now to FIG. 6H, a cross-sectional illustration of the interposer 600 after TGVs 610 and first pads 614 are formed is shown, in accordance with an embodiment. The TGVs 610 and the first pads 614 may be plated with any suitable plating process, such as electrolytic plating. The thickness of the first pads 614 may be thinner than a thickness of the resist layer 625.

Referring now to FIG. 6I, a cross-sectional illustration of the interposer 600 after the resist layer 625 is removed is shown, in accordance with an embodiment. The resist layer 625 may be removed with a resist stripping process or the like. Removal of the resist layer 625 fully exposes the first pads 614.

Referring now to FIG. 6J, a cross-sectional illustration of the interposer 600 after second pads 612 are formed is shown, in accordance with an embodiment. In an embodiment, the second pads 612 may be formed by removing the dielectric layer 651 and using the copper foil 652 as a seed layer to plate the second pads 612. After plating, the copper foil 652 may be removed. In an embodiment, a surface finish 621 and an adhesion promoting layer 622 may be provided on and/or over the second pads 612. In an embodiment, a solder resist layer 620 is provided over the backside surface of the substrate 601. Solder resist openings may expose the underlying second pads 612.

Referring now to FIG. 6K, a cross-sectional illustration of the interposer 600 after a bridge 630 is inserted into the cavity 605 is shown, in accordance with an embodiment. In an embodiment, the bridge 630 is coupled to the first pads 614 by interconnects 633, such as solder balls. The bridge 630 may include pads 631 coupled to the interconnects 633. Vias 632 through the bridge 630 may couple pads 631 to pads 634. Bumps 635 may be provided over the pads 634. In an embodiment, the interconnects 633 may be surrounded by an underfill 606. A cavity fill layer 607 may fill a remainder of the cavity 605.

Referring now to FIG. 6L, a cross-sectional illustration of the interposer 600 after first dies 641 and a second die 642 are attached is shown, in accordance with an embodiment. In an embodiment, the first dies 641 and the second die 642 may be coupled to the bumps 635 by bumps 643 or any other suitable FLI architecture. The first dies 641 may be PICs and the second die 642 may be a compute die, such as a processor, an ASIC, or the like. In an embodiment, the first dies 641 may be optically coupled to a fiber connector by waveguides (not shown) provided in or on the substrate 601.

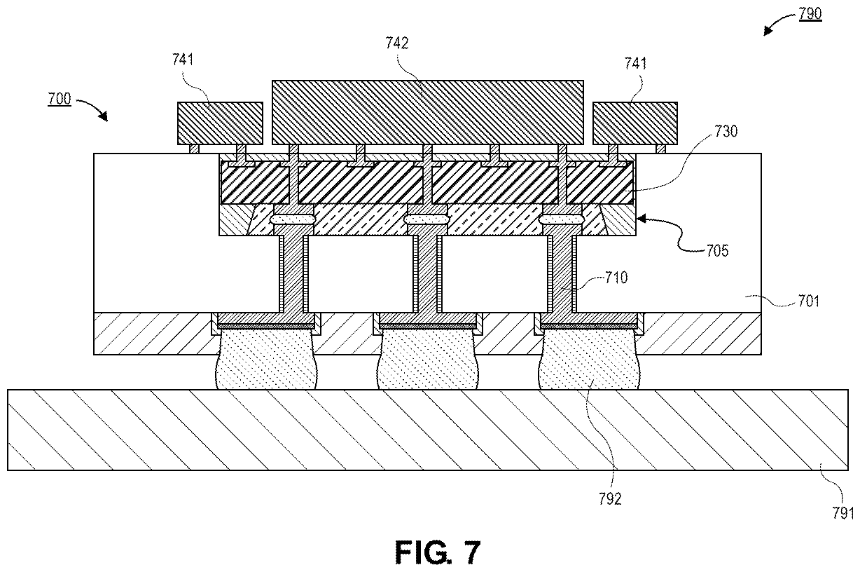

Referring now to FIG. 7, a cross-sectional illustration of an electronic system 790 is shown, in accordance with an embodiment. As shown, the electronic system 790 comprises a board 791, such as a printed circuit board (PCB). In some embodiments, the board 791 may be separated from the interposer 700 by a package substrate, such as an organic package substrate. In such an embodiment, the package substrate may then be coupled to the board 791. In an embodiment, the board 791 is coupled to the interposer 700 by interconnects 792, such as solder interconnects. Though, it is to be appreciated that any interconnect architecture may be used.

In an embodiment, the interposer 700 comprises a substrate 701, such as a glass substrate 701. The substrate 701 may include a cavity 705. A bridge 730 may be inserted into the cavity 705. The bridge 730 may be coupled to a backside of the substrate 701 by TGVs 710 that are below the cavity. In an embodiment, the bridge 730 electrically couples first dies 741 to a second die 742 with high density routing on the bridge 730. The first dies 741 may comprise PICs and the second die 742 may be a compute die, such as a processor, an ASIC, or the like. In an embodiment, the first dies 741 may be optically coupled to a fiber connector by a waveguide (not shown) on or in the substrate 701. In the illustrated embodiment, the interposer 700 is substantially similar to the interposer 100 described with respect to FIG. 1. However, it is to be appreciated that any of the interposer architectures described herein may be used in the electronic system 790.

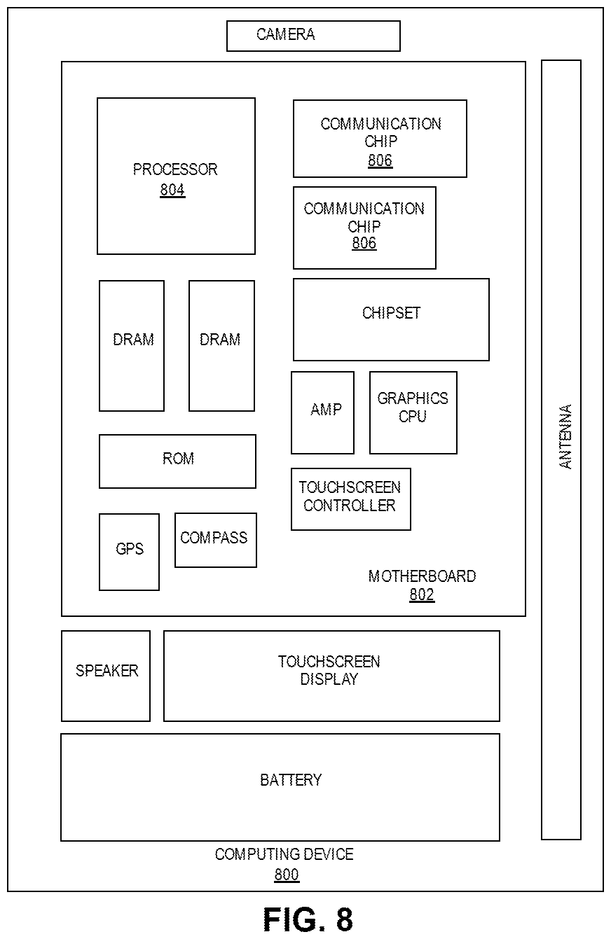

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic system that includes a glass interposer with a cavity and TGVs, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic system that includes a glass interposer with a cavity and TGVs, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an interposer, comprising: a substrate with a first surface and a second surface opposite from the first surface, wherein the substrate comprises glass; a cavity into the first surface of the substrate; a via through the substrate below the cavity; a first pad in the cavity over the via; and a second pad on the second surface of the substrate under the via.

Example 2: the interposer of Example 1, wherein the first pad is coupled to a bridge in the cavity.

Example 3: the interposer of Example 2, wherein a second via passes through a thickness of the bridge.

Example 4: the interposer of Example 2 or Example 3, wherein the bridge couples a first die to a second die.

Example 5: the interposer of Example 4, wherein the first die is a photonics integrated circuit (PIC), and wherein the second die is a compute die.

Example 6: the interposer of Examples 1-5, wherein the second pad is covered by a surface finish layer.

Example 7: the interposer of Examples 1-6, further comprising: a solder resist over the second surface of the substrate, wherein an opening is formed through the solder resist to expose the second pad.

Example 8: the interposer of Example 7, wherein an interface layer is provided between the second pad and the solder resist.

Example 9: the interposer of Examples 1-8, wherein the via has vertical sidewalls or tapered sidewalls.

Example 10: the interposer of Examples 1-9, wherein the substrate comprises borosilicate glass or fused silica glass.

Example 11: an interposer, comprising: a substrate with a first surface and a second surface opposite from the first surface; a cavity into the first surface of the substrate; a via through the substrate below the cavity, wherein the via includes a protrusion that extends up into the cavity; and a bridge in the cavity that is coupled to the via.

Example 12: the interposer of Example 11, wherein the substrate has a curved surface adjacent to the via.

Example 13: the interposer of Example 11 or Example 12, further comprising: a seed layer on sidewalls of the via.

Example 14: the interposer of Examples 11-13, wherein the seed layer extends up the protrusion.

Example 15: the interposer of Examples 11-14, wherein the via is coupled to a pad on the second surface of the substrate.

Example 16: the interposer of Examples 11-15, wherein the substrate comprises glass.

Example 17: the interposer of Examples 11-16, wherein the via has vertical sidewalls.

Example 18: the interposer of Examples 11-16, wherein the via has tapered sidewalls.

Example 19: the interposer of Examples 11-18, wherein a solder bump couples the protrusion to the bridge.

Example 20: an interposer, comprising: a substrate with a first surface and a second surface opposite from the first surface; a cavity into the first surface of the substrate; a via through the substrate under the cavity; and a liner around the via.

Example 21: the interposer of Example 20, wherein the liner comprises silicon and nitrogen.

Example 22: the interposer of Example 21, wherein the liner is separated from the via by a seed layer.

Example 23: the interposer of Example 21 or Example 22, wherein the substrate comprises glass.

Example 24: an electronic system, comprising: a board; an interposer coupled to the board, wherein the interposer comprises: a substrate with a first surface and a second surface opposite from the first surface, wherein the substrate comprises glass; a cavity into the first surface of the substrate; a via through the substrate below the cavity; a bridge in the cavity coupled to the via; and a pad coupled to the via on the second surface of the substrate, wherein the pad is coupled to the board by an interconnect; and a first die and a second die coupled to the interposer, wherein the bridge electrically couples the first die to the second die.

Example 25: the electronic system of Example 24, wherein the first die is a photonics integrated circuit (PIC), and wherein the second die is a compute die.

What is claimed is:

1. An interposer, comprising:
a substrate with a first surface and a second surface opposite from the first surface, wherein the substrate comprises glass;
a cavity into the first surface of the substrate;
a via through the substrate below the cavity;
a first pad in the cavity over the via; and
a second pad on the second surface of the substrate under the via.

2. The interposer of claim 1, wherein the first pad is coupled to a bridge in the cavity.

3. The interposer of claim 2, wherein a second via passes through a thickness of the bridge.

4. The interposer of claim 2, wherein the bridge couples a first die to a second die.

5. The interposer of claim 4, wherein the first die is a photonics integrated circuit (PIC), and wherein the second die is a compute die.

6. The interposer of claim 1, wherein the second pad is covered by a surface finish layer.

7. The interposer of claim 1, further comprising:
a solder resist over the second surface of the substrate, wherein an opening is formed through the solder resist to expose the second pad.

8. The interposer of claim 7, wherein an interface layer is provided between the second pad and the solder resist.

9. The interposer of claim 1, wherein the via has vertical sidewalls or tapered sidewalls.

10. The interposer of claim 1, wherein the substrate comprises borosilicate glass or fused silica glass.

11. An interposer, comprising:
a substrate with a first surface and a second surface opposite from the first surface;
a cavity into the first surface of the substrate;
a via through the substrate below the cavity, wherein the via includes a protrusion that extends up into the cavity; and
a bridge in the cavity that is coupled to the via.

12. The interposer of claim 11, wherein the substrate has a curved surface adjacent to the via.

13. The interposer of claim 11, further comprising:
a seed layer on sidewalls of the via.

14. The interposer of claim 11, wherein the seed layer extends up the protrusion.

15. The interposer of claim 11, wherein the via is coupled to a pad on the second surface of the substrate.

16. The interposer of claim 11, wherein the substrate comprises glass.

17. The interposer of claim 11, wherein the via has vertical sidewalls.

18. The interposer of claim 11, wherein the via has tapered sidewalls.

19. The interposer of claim 11, wherein a solder bump couples the protrusion to the bridge.

20. An interposer, comprising:
a substrate with a first surface and a second surface opposite from the first surface;
a cavity into the first surface of the substrate;
a via through the substrate under the cavity; and
a liner around the via.

21. The interposer of claim 20, wherein the liner comprises silicon and nitrogen.

22. The interposer of claim 21, wherein the liner is separated from the via by a seed layer.

23. The interposer of claim 21, wherein the substrate comprises glass.

24. An electronic system, comprising:
a board;
an interposer coupled to the board, wherein the interposer comprises:
a substrate with a first surface and a second surface opposite from the first surface, wherein the substrate comprises glass;
a cavity into the first surface of the substrate;
a via through the substrate below the cavity;
a bridge in the cavity coupled to the via; and
a pad coupled to the via on the second surface of the substrate, wherein the pad is coupled to the board by an interconnect; and
a first die and a second die coupled to the interposer, wherein the bridge electrically couples the first die to the second die.

25. The electronic system of claim 24, wherein the first die is a photonics integrated circuit (PIC), and wherein the second die is a compute die.
